(19) United States
(12) Patent Application Publication
(10) Pub. No.: US 2005/0266602 A1
(43) Pub. Date: Dec. 1, 2005

(54) Encapsulated chip and method of fabrication thereof

(75) Inventor: Brad L. Hawthorne, Saratoga, CA (US)

Correspondence Address: WALLACE G. WALTER, 5726 CLARENCE AVE, ALEXANDRIA, VA, 22311-1008, US

(73) Assignee: Intersil Americas, Inc.

(21) Appl. No.: 11/034,871

(22) Filed: Jan. 14, 2005

Related U.S. Application Data
(60) Provisional application No. 60/575,096, filed on May 28, 2004.
(60) Provisional application No. 60/575,101, filed on May 28, 2004.

(51) Int. Cl. H01L 21/00

(52) U.S. Cl. 438/64; 438/65

(57) ABSTRACT

A method of fabricating an integrated circuit having an optically transmissive window therein includes forming an integrated chip preform structure that includes a plurality of bonding wires connecting pads on a die structure to pads on a lead frame structure, at least some of the bonding wires having a selected portion, such as a looped portion, that defines or establishes a common mounting plane or support surface therebetween. A quantity of an uncured or partially cured optically transmissive material is deposited on the die portion of the integrated circuit preform and the window is thereafter placed on the uncured or partially cured optically transmissive material and positioned so that the window is on or in the mounting plane or support surface defined by the bonding wires. The so-assembled components are then subject to a curing step to cure the optically transmissive media and thereafter subject to an encapsulation step. If desired the curing step and the encapsulation step can be partially or fully concurrent with one another. The resulting integrated chip package utilizes the mounting or support plane defined by or established by the bonding wires to efficiently maintain the position of the window during fabrication.

### CROSS-REFERENCE TO RELATED APPLICATION

This application claims the benefit of commonly owned U.S. Provisional Patent Application 60/575,096 filed by the inventor herein on May 28, 2004. This application is related to commonly owned U.S. Provisional Patent Application 60/575,101 filed May 28, 2004 by the inventor herein and U.S. Patent Application (Docket SE-2055) filed on even date herewith by the inventor herein, both entitled “Method Of Fabricating An Encapsulated Chip And Chip Produced Thereby.”

### BACKGROUND OF THE INVENTION

The present invention relates to the fabrication of encapsulated integrated circuits and, more particularly, to a method for the fabrication of an encapsulated integrated circuit having optically active areas or devices therewith and the encapsulated integrated circuits resulting therefrom.

Integrated circuit devices that include an optically active area or areas typically incorporate a window of glass, quartz, plastic, or similar material(s) that allows the transmission of optical energy therethrough to and/or from the optically active area or areas of the chip structure. Typically, the window is located on the top surface of the encapsulated chip and allows optical energy to pass to and/or from the optically active areas of the underlying die. In general, it is desirable to reduce the fabrication costs of such integrated circuits, since the placement and alignment of the window oftentimes requires the use of specially designed posts, columns, or similar structures to hold the window in place relative to the underlying die during the encapsulation process.

### SUMMARY OF THE INVENTION

An integrated circuit includes an optically transmissive window through which optical energy passes to and/or from an optically active area or areas formed in or on an underlying semiconductor die. A plurality of bonding wires connect pads on the die with corresponding contacts or pads on a surrounding lead frame structure with the various bonding wires formed with a looped portion, the uppermost reach or extent of the looped portion of at least some of the bonding wires defining a mounting plane or support surface upon which or in which the window is located.

A method of fabricating an integrated circuit having an optically transmissive window therein includes forming an integrated chip preform structure that includes a plurality of bonding wires connecting pads on a die structure to pads on a lead frame structure, at least some of the bonding wires having a looped portion that defines or establishes a common mounting plane or support surface therebetween. A quantity of an uncured or partially cured optically transmissive material is deposited on the die portion of the integrated circuit preform and the window is thereafter placed on the uncured or partially cured optically transmissive material and positioned so that the window is on or in the mounting plane or support surface defined by the bonding wires. The so-assembled components are then subject to a curing step to cure the optically transmissive media and thereafter subject to an encapsulation step. If desired the curing step and the encapsulation step can be partially or fully concurrent with one another.

The particular bonding wires used to define the mounting plane or support surface can be active circuit wires, or, if desired, extra “dummy” or otherwire inactive wires.

The method of the present invention uses the looped portions of at least some of the bonding wires to establish the dimensional relationship and/or alignment between the window and the underlying die while the optically transmissive material is in its uncured state to thereby reduce the in-process assembly costs of the resulting package.

The full scope of applicability of the present invention will become apparent from the detailed description to follow, taken in conjunction with the accompanying drawings, in which like parts are designated by like reference characters.

### BRIEF DESCRIPTION OF THE DRAWING

FIG. 1 is a side elevational view, in cross-section, of an exemplary integrated circuit chip structure in accordance with the preferred embodiment;

FIG. 2 is a side elevational view of a die or chip mounted on an underlying lead frame;

FIG. 3 is a side elevational view of the die of FIG. 2 in which bonding wires electrically connect conductive pads on the die to selected leads on the lead frame;

FIG. 4 is a side elevational view of the assembly of FIG. 3 with a deposit of uncured optical coupling media deposited on the face of the die;

FIG. 5 is a side elevational view of the assembly of FIG. 4 with a window placed atop the deposit of uncured optical coupling media;

FIG. 6 is a side elevational view of the assembly of FIG. 5 with the window depressed or pressed a selected distance into the deposit of uncured optical coupling media and positioned atop or adjacent the bonding wires;

FIG. 7 illustrates the optional use of an anti-flash tape placed on the window to limit or prevent encapsulation material from covering the window surface;

FIG. 8 is a representative perspective view of a portion of QFN-type package in which two of the bonding wires are installed with an elevation higher then the others;

FIG. 9 is a side elevational view of the assembly of FIG. 8 with a deposit of uncured optical coupling media deposited on the face of the die;

FIG. 10 is a side elevational view of the assembly of FIG. 9 the window depressed or pressed a selected distance into the deposit of uncured optical coupling media and positioned atop or adjacent the higher elevation bonding wires

FIG. 11 is a side elevational view of variant of the the assembly of FIG. 8 in which the ‘corner’ bonding wires are at a higher elevation than the other bonding wires; and

FIG. 12 is a top view of the structure of FIG. 11.

### DESCRIPTION OF THE INVENTION

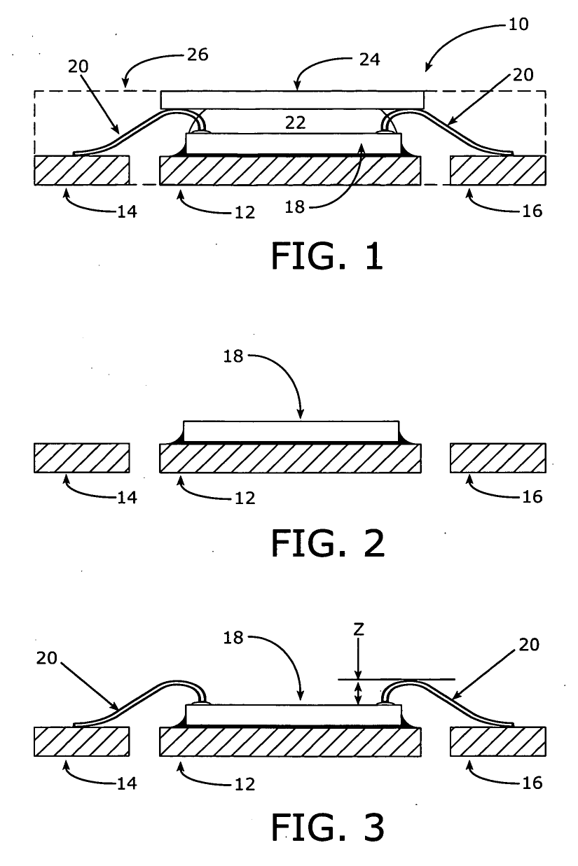

An encapsulated semiconductor device of the type fabricated in accordance with the present invention is shown in exemplary cross-section in FIG. 1 and is designated therein by the reference character 10. As shown, the semiconductor device 10 includes a die pad 12 that can be part of a larger lead frame or similar structure of which leads 14 and 16 are representative. An integrated circuit die 18 is affixed to one surface of the die pad 12 by a conventional die attach adhesive or cement (unnumbered). Conductive pads or lands (not shown) on the die 18 are electrically connected to the various leads by conductors, i.e., bonding wires 20 (typically gold or aluminum or alloys thereof), that are secured in place on their respective pads or lands by suitable bonding techniques including, for example, thermocompression or thermosonic techniques or variants thereof. An optical coupling media 22 is located over and occupies a selected volume on the top surface of the die 18 and is designed, as explained more fully below, to transmit or couple optical energy to and/or from optical devices formed in or on the die 18. A window 24 is located on or in engagement with the optical coupling media 22 and acts as the interface between the interior components of the semiconductor device 10 and the exterior thereof. Lastly, an encapsulating material 26, such as a conventional opaque resin or epoxy material, surrounds the interior components to define the outline of the semiconductor package 10.

A first embodiment of the semiconductor device 10 of FIG. 1 is prepared in accordance with the sequence of FIGS. 2-7. The embodiment of FIGS. 2-7 is described in the context of a QFN “no-lead” type package; as can be appreciated, the invention is not so limited and can be used in the context of other types of semiconductor packages, including, for example, ball-grid arrays, pin arrays, and classic dual-in-line packages.

As shown in FIG. 2, the circuit die 18 is attached to the die pad 12 using a conventional die attach adhesive or cement. In automated systems, the die 18 can be attached using conventional pick-and-place robotic machinery. The die 18 includes one or more optical devices or circuits formed therein or thereon. The optical devices can include devices for responding to incident optical radiation or for generating and emitting optical radiation including, for example, photoreceptive diodes/transistors and/or photoemitting photodiodes, LEDs, lasers, or the like. As used herein, optical devices are those that either respond to and/or emit radiation from and between the infrared region through the visible region and into and through the ultraviolet region of the electromagnetic spectrum.

As represented in FIG. 3 and after the placement of the die 18 on its die pad 12, the die 18 is electrically connected to its lead frame using conventional bonding wires 20. More specifically, individual conductive pads (not shown) on the die 18 are connected to respective leads (as represented by the leads 14 and 16) by wires 20 using conventional ball bond (i.e., “nail-head”) or wedge bond formations and thermocompressive, thermosonic, or equivalent bonding techniques. The bonding wires 20 are typically installed by automatic wiring machines, which, as is known in the art, can be programmed to attach the ends of the individual bonding wires 20 at precise x,y locations and control the height of the wire loop relative to some arbitrary datum. In FIG. 3, the height dimension “Z” is defined or established between the upmost extend or “reach” of the looped portion of the bonding wire 20 and the top surface of the die 18, although other surfaces, such as the top or bottom surface of the die pad 12, are equally suitable and can be used as the datum surface. As can be appreciated, the upmost extend or “reach” of the looped portion of three or more bonding wires 20 define or establish a mounting surface or plane therebetween.

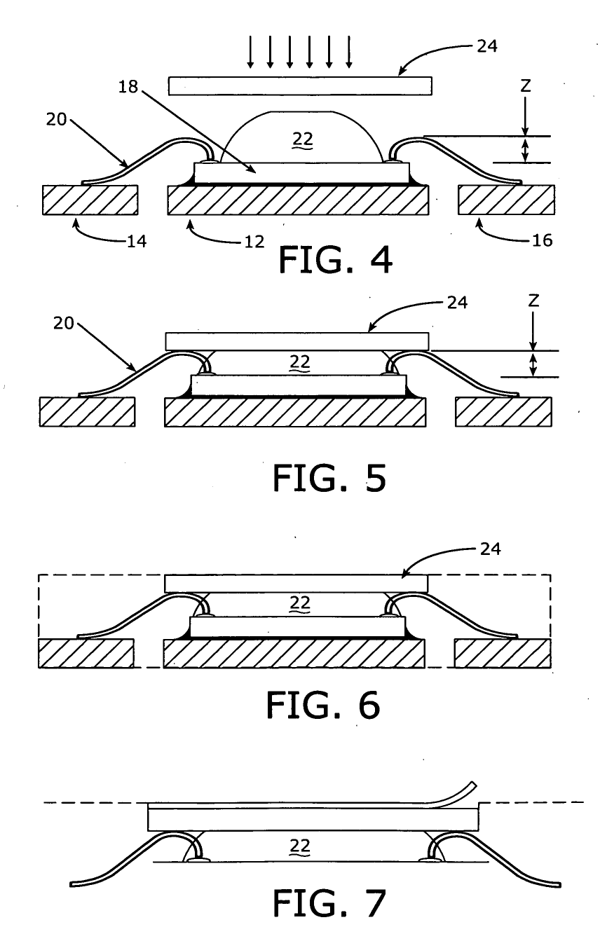

After the wire bonding step is completed and as shown in FIG. 4, a selected volume of an optical coupling media 22 is deposited on the exposed surfaces of the die 18. The optical coupling media 22 is typically an uncured or partially cured optical material such as an epoxy, acrylate, resin, or silicone that, in its cured state, is sufficiently transparent to transmit or convey optical energy to and/or from the optical devices or circuits formed on or in the die 18. In a preferred application of the present invention, HIPEC® Q1-4939 solventless silicone gel from the Dow Corning Corp., Midland, Mich. 48686 is used. This material, in its initial uncured state, is applied as a soft, pliable gel to the surface of the die 18 and cures into a resilient elastomeric material; the material used can be applied in its initially mixed uncured state or in a partially cured state. As is known, the as-applied viscosity of the silicone gel can be controlled in accordance with the supplier's instructions. If desired, other materials, including conventional hardenable epoxies and resins can be used as the optical coupling media 22, provided they possess adequate optical and mechanical properties for the intended application.

Once the optical coupling media 22 is deposited on the die 18 and as shown in FIGS. 4 and 5, the window 24 is placed on the deposited material. The window 24 can take the form of a glass, quartz, silica, or plastic material appropriately sized for the die 18 and the application. In the preferred embodiment, the window 24 is formed from conventional amorphous glass that is saw-cut from larger sheets into the desired size, which size is sufficiently large that some portion of the window 24 is located above the looped portions of at least a plurality of the bonding wires 20. If desired, the particular material from which the window is formed can have uniform or non-uniform transmission characteristics for the wavelength or wavelengths to be transmitted to and/or from the die 18, and, optionally, can be provided with one or more coatings to enhance or otherwise control its optical properties and/or provide physical abrasion resistance to the exposed surface of the window 24. In automated assembly systems, the window 24 can be positioned and placed upon the optical coupling media 22 by a conventional pick-and-place robotic system.

As shown in FIG. 5, the window 24 is placed atop the optical coupling media 22 and is pressed into or depressed into the optical coupling media 22 as part of the window placement operation until the bottom surface of the window 24 rests atop or immediately adjacent the uppermost extent or reach of at least a plurality of the bonding wires 20. As the window 24 is pushed into the optical coupling media 22, the media will tend to laterally displace somewhat; in general, this peripheral spreading or “bleeding” results in an acceptable lateral or peripheral expansion of the optical coupling media 22. In general, the uppermost extent or reach of a majority of the bonding wires 20 will define a surface spaced by the dimension “Z” from the datum. Thus, by placing the window 24 on or atop the uppermost extent of reach of the bonding wires 20, the window 24 will be thereby be positionally supported on a surface or plane defined by the uppermost extent or reach of the bonding wires. In practice, some dimensional variation exists in the looping of the bonding wires such that the uppermost extent or reach of some of the bonding wires may be less that of others. While it is desired that the uppermost extent or reach of all the bonding wires 20 participate in defining the support surface or plane upon which the window 24 is positioned, as a practical matter, at least some of the bonding wires may not extend sufficiently to support the window 24. In general, as few as three sufficiently spaced-apart bonding wires 20 can successfully define the “Z” support surface or plane on which or in which the window 24 is positioned.

While it is contemplated that the bottom surface of the window 24 contact the top of the bonding wire loops that define the “Z” surface, the volume of optical coupling media 22 applied to the die 18 and the use of higher viscosity or “stiffer” optical coupling medias may create a layer of optical coupling media that separates the bottom surface of the window 24 from the top of the bonding wire loops that define the “Z” support surface or plane. In this situation and because of the viscosity or “stiffness” of optical coupling media, the bonding wires nonetheless function to positionally define the window 24, by virtue of this window-supporting layer, even in the absence of direct window-to-wire contact. As can be appreciated, the support surface or plane defined by at least some of the bonding wires 20 serves to positionally define or maintain the as-placed window on the uncured or partially cured optical coupling media 22.

While the window 24 can be “placed” in its supported position relative to the wires and, depending upon the viscosity/density/cure-state of the optical coupling media, allowed to ‘sink’ or settle onto those wires that define the window support plane or surface, the window 24, if desired, can be pressed downward onto the wires or pressed downward with sufficient force to cause the wires 20 to be momentarily and resiliently depressed to increase the probability of all the wires participating in the window-support function will contact the window, or, if desired, the window 24 can be pressed downward with sufficient force to cause a small permanent deformation or yielding of the wires 20 to increase the probability of all the wires participating in the window-support function. The issue of whether the window 24 is merely placed in position on or in the wire-defined mounting surface or plane, pressed downward, resiliently pressed downward, or pressed downward to cause the wires to permanently yield is a function of the particular application.

In FIGS. 4 and 5 and as described above, the optical coupling media 22 is deposited upon the die 18 (FIG. 4) and the window 24 is thereafter pressed or depressed into the so-deposited material (FIG. 5). As can be appreciated, some or all of the optical coupling media can be deposited on the underside of the window 24 and the window 24 with its deposit of optical coupling media 22 can be pressed onto or assembled to the pre-form assembly of FIG. 3.

After the window 24 is placed upon the as-applied uncured or partially cured optical coupling media 22, the assemblage of FIG. 5 is subject to a full or partial curing step by application of heat at a temperature and duration appropriate for the optical curing media used. For individual piece-parts and small batch quantities, curing can be accomplished in conventional “box” ovens and for large quantities, production ovens/molds can be used. In the case of the HIPEC® media mentioned above, exposure to 150° C. for about two hours is sufficient to effect a cure.

After the optical coupling media is fully cured or at least sufficiently cured for the assemblage of FIG. 5 to undergo encapsulation, the assembly of FIG. 5 can be placed in a conventional encapsulation mold and subject to an encapsulation step by which the typically opaque encapsulating material defines the final or near final semiconductor package.

It is not necessary for the curing of the optical coupling media 22 to be completed prior to the conventional encapsulation procedure. For example, the optical coupling media 22 can be subject to curing for a sufficient period of time such that the now-partially but not fully cured optical coupling media 22 will remain dimensionally stable during the subsequent encapsulation step so that the curing of the encapsulation material will concurrently “finish” the curing of the optical coupling media 22.

If desired and as shown in FIG. 7, a removable adhesive-backed “anti-flash” tape 30 can be provided on the exterior surface of the window 24. This tape 30, which is shown partially “peeled” from the window 24 in FIG. 7, functions to protect the surface of the window 24 during processing and functions to temporarily seal the peripheral margins of the window 24 during the encapsulation step to minimize or prevent any encapsulation material from infiltrating onto the exterior surface of the window 24. Once the encapsulation step is completed, the tape 30 can be removed manually or by use of solvents and/or washes. Where an anti-flash tape 30 is not used, conventional flash-removing solvents, baths, and/or washes can be used.

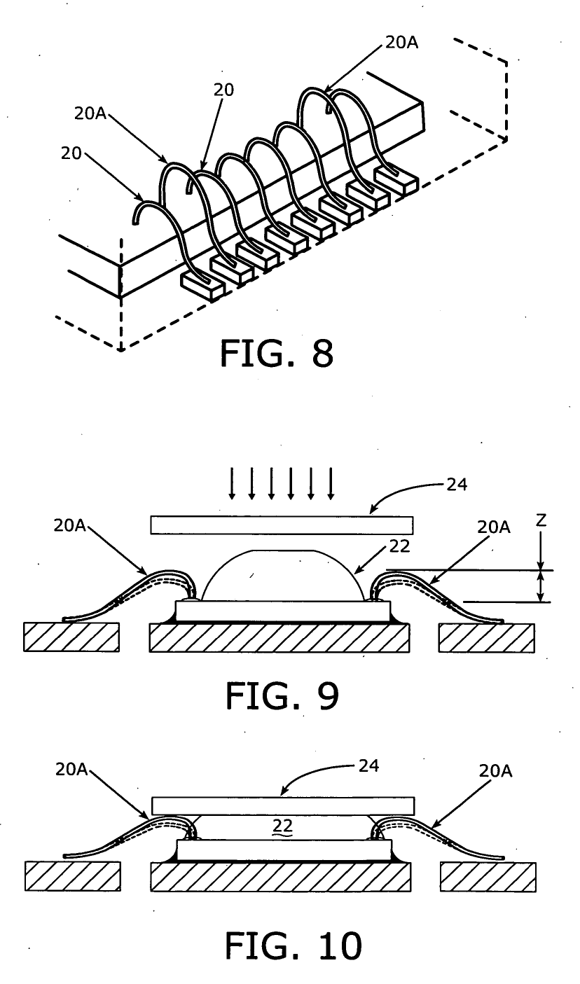

In the embodiment described above, the bonding wires 20 are nominally installed with a looped portion, the uppermost reach or extent of which defines the “Z” surface upon which or by which the window 24 is positionally supported or positionally defined. In a variation of the above-described embodiment, a sub-set of the bonding wires are formed with an uppermost reach or extent that is higher than the others. As shown in diagrammatic fashion in FIG. 8, two of the bonding wires, designated as 20A, are formed with an uppermost reach or extent that is higher than that of the other bonding wires 20. The “package” shown in FIG. 8 is representative of QFN type packages and shows only one side of a multi-sided package. As can be appreciated, one or more bonding wires 20A on other sides of the package can be provided so that a sub-set of the bonding wires have loops with an uppermost reach or extent that is higher than the others with that sub-set of bonding wires defining the support plane or mounting surface upon which the window 24 is positioned on or in.

In FIG. 9, the higher elevation bonding wires 20A (solid-line illustration) are shown relative to the lower elevation bonding wires 20 (dotted-line illustration). In the embodiment of FIG. 9, the window 24 is placed in the same manner as that for the embodiment of FIGS. 1-7, however, only a sub-set of the bonding wires, i.e., the bonding wires 20A, serve to define or establish the support plane or surface for the window 24. In theory, only three bonding wires 20A, spaced-apart in a tripod “footprint” will provide adequate support, although more than three such bonding wires 20A may be indicated. For those chips circuits in which alternate bonding wires are ground wires, these ground wires can function as the higher-elevation bonding wires 20A.

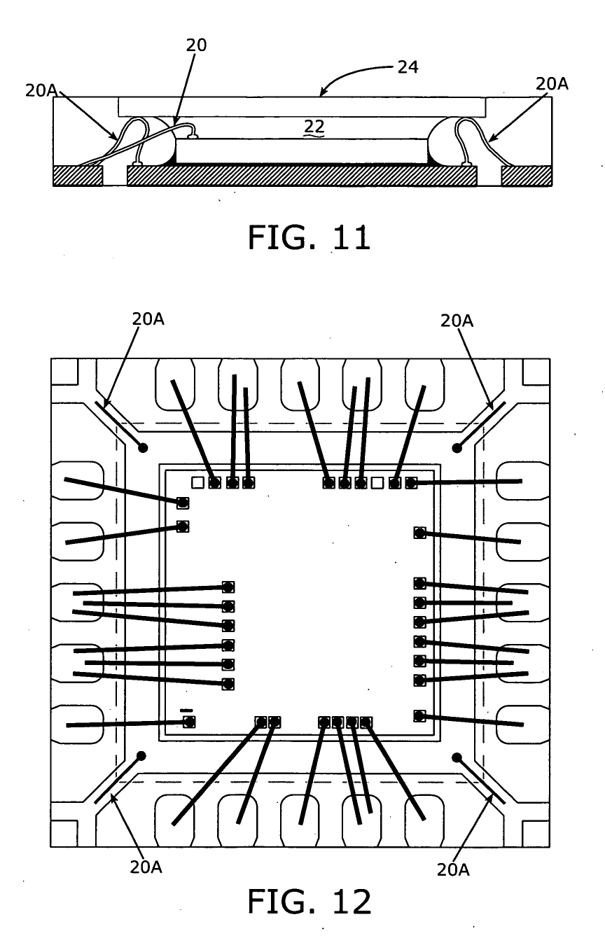

A futher variant of the present invention in shown in FIGS. 11 and 12; as shown on the left in FIG. 11, support wires 20A have an inverted “U” shaped relative to the bonding wires 10. In FIGS. 11 and 12, the support wires 20A are “dummy” or extra wires located and the corners of the die. More specifically and as shown in the plan view of FIG. 12, a support wire 20A is located at each corner of the die and cooperate to define the window support plane or surface. In the embodiment of FIGS. 11 and 12, the optical coupling media, in general, is not suffused in and between the various wires 20 or 20A and, according, the upper most reach of the loop portion of the support wires 20A is available for contact with the underside of the window 24.

In the preferred embodiments described above, the bonding wires are described as having looped portions that define an uppermost reach or extent to define the mounting surface or support plane; these looped portions often identified in the art as a “flat loop” or a “worked loop.” As can be appreciated, the invention is not so limited can including other bonding wire configurations and organizations, including bonding wires in which each bonding wire extends from the conductive pad on the die to an attachment point in a relatively straight line so that some segment of the relatively straight bonding wires defines the support plane or mounting surface for the window. While the some of the bonding wires have been described as having an uppermost reach that defines the support plane, variants include bonding wire shapes in which a shelf or ledge is provided below the uppermost reach and which define the support plane.

The present invention thus provides a method for forming a semiconductor device package of the type having an optical window therein and the product formed thereby.

As will be apparent to those skilled in the art, various changes and modifications may be made to the illustrated embodiment of the present invention without departing from the spirit and scope of the invention as determined in the appended claims and their legal equivalent.

1. An method of fabricating a semiconductor device having an optical interface, the semiconductor device including a die having an optical component or components thereon or therein, comprising:
attaching connecting wires to selected pads on the die to selected contacts on a lead frame associated with the die, at least some of the wires having selected wire portions thereof defining a mounting plane or surface therebetween;
depositing a selected quantity of an uncured or partially cured optically transmissive material on at least that portion or those portions of the die having the optical component or components thereon or therein;
placing an optically transmissive window on the deposit of optically transmissive material and positioning the optically transmissive window in or on the mounting plane or surface defined by said selected wire portions; and
curing the optically transmissive material.

2. The method of claim 1, wherein said placing step places the optically transmissive window in a supporting relationship with the selected wire portions that define the mounting plane or surface.

3. The method of claim 1, wherein said placing step places the optically transmissive window in contact with the selected wire portions that define the mounting plane or surface.

4. An method of fabricating a semiconductor device having an optical interface, the semiconductor device including a die having an optical component or components thereon or therein, comprising:
attaching connecting wires to selected pads on the die to selected contacts on a lead frame associated with the die, at least some of the wires having a looped portion, the uppermost reach or extent of the looped portion defining a mounting plane or surface therebetween, the mounting plane or surface spaced a selected distance from the die;
depositing a selected quantity of an uncured or partially cured optically transmissive material on at least that portion or those portions of the die having the optical component or components thereon or therein;
placing an optically transmissive window on the deposit of optically transmissive material and positioning the optically transmissive window in or on the mounting plane or surface defined by the looped portions; and
curing the optically transmissive material.

5. The method of claim 4, wherein said placing step places the optically transmissive window in a supporting relationship with the looped portions that define the mounting plane or surface.

6. The method of claim 4, wherein said placing step places the optically transmissive window in contact with the looped portions that define the mounting plane or surface.

7. An method of fabricating a semiconductor device having an optical interface, the semiconductor device including a die having an optical component or components thereon or therein, comprising:
attaching connecting wires to selected pads on the die to selected contacts on a lead frame associated with the die, at least some of the wires having a looped portion, the uppermost reach or extent of the looped portion defining a mounting plane or surface therebetween;
depositing a selected quantity of an uncured or partially cured optically transmissive material on an optically transmissive window;
placing the optically transmissive window and its deposit of optically transmissive material over least that portion or those portions of the die having the optical component or components thereon or therein and positioning the optically transmissive window in or on the mounting plane or surface defined by the looped portions; and
curing the optically transmissive material.

8. The method of claim 7, wherein said placing step places the optically transmissive window in a supporting relationship with the selected wire portions that define the mounting plane or surface.

9. The method of claim 7, wherein said placing step places the optically transmissive window in contact with the selected wire portions that define the mounting plane or surface.

10. A semiconductor device having an optically transmissive window therein for coupling optical energy to and/or from optical components formed in or on a semiconductor die within the device, comprising:
a semiconductor die having conductive pads thereon and having an optically active component or components formed thereon or therein;
a plurality of wires connecting the conductive pads of said semiconductor die to respective leads, at least some of said wires having a respective portion thereof defining a support surface or plane spaced a selected distance relative to a selected datum;
a window positioned on or in the support surface or plane, at least some of said wires in a support relationship with said window to support said window in or on said support surface or plane; and
an optically transmissive media substantially filling the space between said the optically active components or components of said die and the window.

11. The semiconductor device of claim 10, further comprising an encapsulating material forming an encapsulation package, at least one surface of the window substantially free of the encapsulating material.

12. The semiconductor device of claim 10, wherein the respective portion of each wire defining said support surface is a looped portion.
